(19) United States
(12) Patent Application Publication
(10) Pub. No.: US 2015/0243367 A1
(43) Pub. Date: Aug. 27, 2015

(54) SHIFT REGISTER UNIT CIRCUIT, SHIFT REGISTER, ARRAY SUBSTRATE AND DISPLAY DEVICE

(71) Applicants: BOE TECHNOLOGY GROUP CO., LTD., Beijing (CN); HEFEI BOE OPTOELECTRONICS TECHNOLOGY CO., LTD., Hefei, Anhui (CN)

(72) Inventors: Xiaofang Gu, Beijing (CN); Rui Ma, Beijing (CN); Ming Hu, Beijing (CN)

(73) Assignees: Boe Technology Group Co., Ltd. et al.; Hefei Boe Optoelectronics Technology Co., Ltd. et al.

(21) Appl. No.: 14/429,877

(22) PCT Filed: Jun. 30, 2014
(86) PCT No.: PCT/CN2014/081208

§ 371 Date: Mar. 20, 2015

(30) Foreign Application Priority Data
Sep. 2, 2013 (CN) 201310393435.2

(51) Int. Cl. G11C 19/28; G09G 3/36

(52) U.S. Cl. CPC G11C 19/28; G09G 3/3648; G09G 2300/0809; G09G 2310/0286

(57) ABSTRACT

There are provided a shift register unit circuit, a shift register, an array substrate and a display device. The shift register unit circuit comprises: an input module configured to receive an input signal and output the input signal to a pulling-up node; an output module configured to receive the input signal and output a driving signal under a control of a first clock signal; a pulling-down module configured to pull down a potential at the pulling-up node and a signal output terminal under a control of a pulling-down node; a pulling-down control module configured to pull down the pulling-down node under a control of the input signal and pull up the pulling-down node under a control of a second clock signal; and a resetting module configured to reset the potential at the pulling-up node and the signal output terminal under a control of a resetting signal. A relatively small number of thin film transistors are used to suppress interference noise in the circuit, which saves wiring space and reduces the area occupied by the shift register unit circuit, so as to realize the narrow frame of the liquid crystal display using the shift register.

### TECHNICAL FIELD

The present disclosure relates to a shift register unit circuit, a shift register, an array substrate, and a display device.

### BACKGROUND

A liquid crystal display (LCD) has advantages of light weight, thin thickness, and low power consumption and so on, and is widely applied in electronic devices such as a TV set, a mobile terminal and the like. There exist inside the liquid crystal display a plurality of pixel units surrounded by data lines and gate lines. When the liquid crystal display displays, progressive scanning of respective pixels are realized by inputting a scanning signal to the gate lines through a gate driver arranged at the edge of the liquid crystal display, while the scanning signal is generated by a shift register in the gate driver. The structure of the common shift register unit circuit has twelve thin film transistors (TFT) and one capacitor, and it utilizes a relatively large number of thin film transistors to reduce noise voltage of the shift register unit circuit, thereby ensuring a stable output of signals. The circuit needs to occupy greater space, which results in that the liquid crystal display using such circuit has a large frame, and thus a narrow frame of the liquid crystal display cannot be realized.

### SUMMARY

Embodiments of the present disclosure provide a shift register unit circuit, a shift register, an array substrate and a display device, so as to realize a narrow frame of a liquid crystal display.

According to one aspect of the present disclosure, there is provided a shift register unit circuit, comprising: an input module configured to receive an input signal, and output the input signal to a pulling-up node; an output module configured to receive an input signal, and output a driving signal under a control of a first clock signal; a pulling-down module configured to pull down a potential at the pulling-up node and a signal output terminal under a control of a pulling-down node; a pulling-down control module configured to pull down the pulling-down node under a control of the input signal, and pull up the pulling-down node under a control of a second clock signal; a resetting module configured to reset the potential at the pulling-up node and the signal output terminal under a control of a resetting signal.

According to another aspect of the present disclosure, there is provided a shift register comprising multiple stages of shift register unit circuits provided in the embodiment of the present disclosure connected in cascades, wherein an input signal of a first stage of shift register unit circuit is a frame start signal; except for the first stage of shift register unit circuit, input signals of remaining respective stages of shift register unit circuits are output signals of a previous stage of shift register unit circuit; except for a last stage of shift register unit circuit, resetting signals of remaining respective stages of shift register unit circuits are output signals of a next stage of shift register unit circuit.

According to another aspect of the present disclosure, there is provided an array substrate comprising the shift register provided in the embodiment of the present disclosure.

According to another aspect of the present disclosure, there is provided a display device comprising the array substrate provided in the embodiment of the present disclosure.

The shift register unit circuit provided in the embodiments of the present disclosure adopts a relatively small number of thin film transistors to suppress interference noise in the circuit, which saves wiring space, and reduces the area occupied by the shift register unit circuit while realizing signal transmission function and noise reduction function of the shift register unit, so as to realize the narrow frame of the liquid crystal display using the shift register.

### BRIEF DESCRIPTION OF THE DRAWINGS

FIG. 1 is a schematic diagram of a shift register unit circuit according to an embodiment of the present disclosure;

FIG. 2 is a schematic diagram of another shift register unit circuit according to an embodiment of the present disclosure;

FIG. 3 is a schematic diagram of a shift register circuit according to an embodiment of the present disclosure;

FIG. 4 is a logic timing diagram of a shift register unit circuit according to an embodiment of the present disclosure.

### DETAILED DESCRIPTION

Specific implementations of the present disclosure will be further described by combining with the accompanying figures. The following embodiments are just used for describing the principle of the present disclosure rather than being used for limiting the protection scope of the present disclosure.

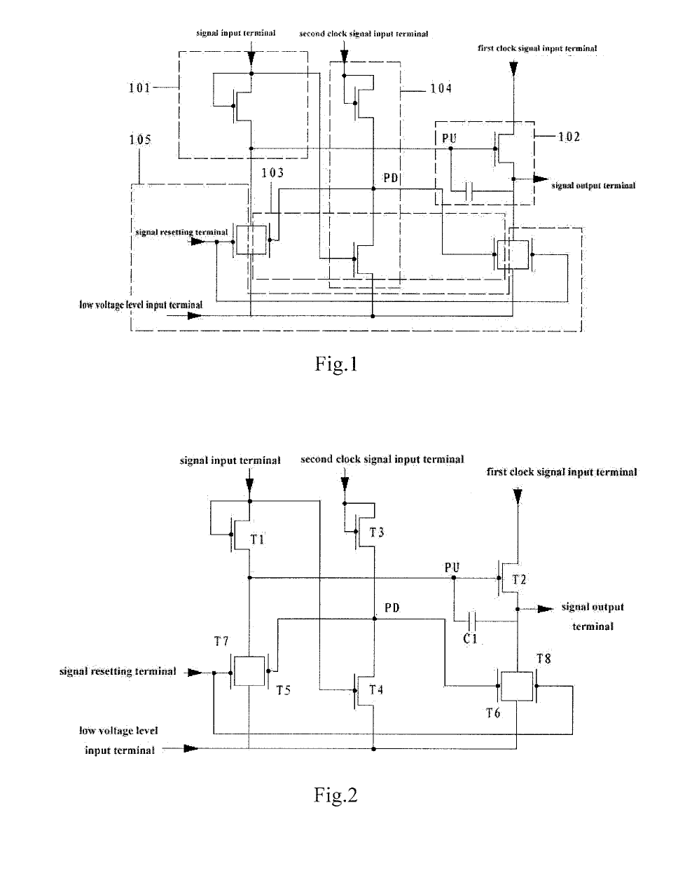

FIG. 1 is a schematic diagram of a shift register unit circuit according to an embodiment of the present disclosure. As shown in FIG. 1, the shift register unit circuit provided in the embodiment of the present disclosure comprises:

an input module 101 configured to receive an input signal, and output the input signal to a pulling-up node PU;

an output module 102 configured to output a driving signal under a control of a first clock signal;

a pulling-down module 103 configured to pull down a potential at the pulling-up node and a signal output terminal under a control of a pulling-down node PD;

a pulling-down control module 104 configured to control a potential at the pulling-down node PD, for example, pulling down the pulling-down node PD under a control of the input signal and pulling up the pulling-down node PD under a control of a second clock signal;

a resetting module 105 configured to reset the potential at the pulling-up node PU and the potential of the signal output terminal under a control of a resetting signal.

The shift register unit circuit provided in the embodiments of the present disclosure adopts a relatively small number of thin film transistors to suppress interference noise in the circuit, which saves wiring space, reduces the number of circuit elements in the shift register unit circuit, and reduces the area occupied by the shift register unit circuit while realizing signal transmission function and noise reduction function of the shift register unit, so as to realize the narrow frame of the liquid crystal display using the shift register.

As shown in FIG. 1, the input module 101 can comprise:

a first thin film transistor, whose gate and drain are connected to a signal input terminal, and source is connected to the pulling-up node PU.

The output module 102 can comprise:

a second thin film transistor, whose gate is connected to the pulling-up node PU, drain is connected to a first clock signal input terminal, and source is connected to the signal output terminal; and

a capacitor, whose first electrode is connected to the pulling-up node PU, and second electrode is connected to the signal output terminal.

The pulling-down control module 104 can comprise:

a third thin film transistor, whose drain and gate are connected to a second clock signal input terminal, and a source is connected to the pulling-down node PD; and

a fourth thin film transistor, whose gate is connected to the signal input terminal, drain is connected to the source of the third thin film transistor, and source is connected to a low voltage level input terminal.

The pulling-down module 103 can comprise:

a fifth thin film transistor, whose gate is connected to the pulling-down node PD, drain is connected to the pulling-up node PU, and source is connected to the low voltage level input terminal; and

a sixth thin film transistor, whose gate is connected to the pulling-down node PD, drain is connected to the signal output terminal, and source is connected to the low voltage level input terminal.

The resetting module 105 can comprise:

a seventh thin film transistor, whose gate is connected to a signal resetting terminal, source is connected to the low voltage level input terminal, and drain is connected to the pulling-up node PU; and

an eighth thin film transistor, whose gate is connected to the signal resetting terminal, drain is connected to the signal output terminal, and source is connected to the low voltage level input terminal.

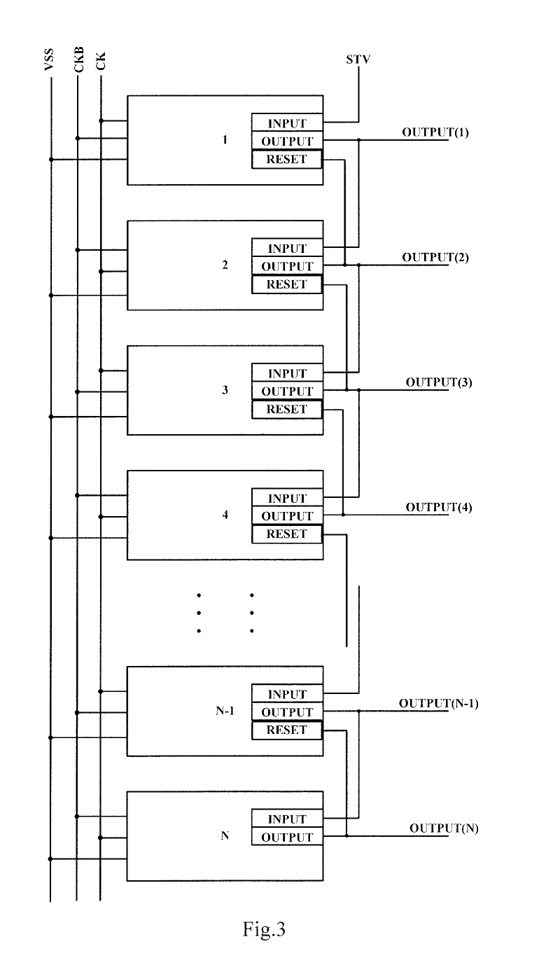

FIG. 2 is a schematic diagram of another shift register unit circuit according to an embodiment of the present disclosure. As shown in FIG. 2, the shift register unit circuit can comprise:

a first thin film transistor T1, whose gate and drain are connected to the signal input terminal;

a second thin film transistor T2, whose gate is connected to the source of the first thin film transistor T1, drain is connected to the first clock signal input terminal, and source is connected to the signal output terminal;

a third thin film transistor T3, whose drain and gate are connected to the second clock signal input terminal;

a fourth thin film transistor T4, whose gate is connected to the signal input terminal, drain is connected to the source of the third thin film transistor T3, and source is connected to the low voltage level input terminal;

a fifth thin film transistor T5, whose gate is connected to the source of the third thin film transistor T3, drain is connected to the source of the first thin film transistor TI, and source is connected to the low voltage level input terminal;

a sixth thin film transistor T6, whose gate is connected to the source of the third thin film transistor T3, drain is connected to the signal output terminal, and source is connected to the low voltage level input terminal;

a seventh thin film transistor T7, whose gate is connected to a signal resetting terminal, source is connected to the low voltage level input terminal, and drain is connected to the pulling-up node;

an eighth thin film transistor T8, whose gate is connected to the signal resetting terminal, drain is connected to the signal output terminal, and source is connected to the low voltage level input terminal; and

a capacitor C1, whose first electrode is connected to the source of the first thin film transistor T1, and second electrode is connected to the signal output terminal.

The pulling-up node PU is located at the first electrode of the capacitor C1, and the pulling-down node PD is located at the source of the third thin film transistor T3.

The second clock signal input terminal is only connected to the third thin film transistor T3, the fourth thin film transistor T4, the fifth thin film transistor T5 and the sixth thin film transistor T6, thereby reducing noise voltage of the shift register unit circuit, ensuring the stable output of signals of the shift register unit circuit, decreasing the number of the circuit elements in the shift register unit circuit, reducing the area occupied by the shift register unit circuit, and further realizing the narrow frame of the liquid crystal display using the shift register.

FIG. 3 is a schematic diagram of a shift register circuit according to an embodiment of the present disclosure. As shown in FIG. 3, the shift register circuit comprises multiple stages of shift register unit circuits as shown in FIG. 1 or FIG. 2 connected in cascades.

In the shift register as shown in FIG. 3, an input signal of a first stage of shift register unit circuit is a frame start signal (STV), except for the first stage of shift register unit circuit, input signals of remaining respective stages of shift register unit circuits are output signals of a previous stage of shift register unit circuit; except for a last stage of shift register unit circuit, resetting signals of remaining respective stages of shift register unit circuits are output signals of a next stage of shift register unit circuit.

Alternatively, all the thin film transistors in the shift register and the shift register circuit described above are N type thin film transistors.

Alternatively, all the thin film transistors in the shift register and the shift register unit circuit as described above are polysilicon thin film transistors simultaneously or amorphous silicon thin film transistors simultaneously.

The operation principle of respective stages of shift register unit circuits in the shift register as shown in FIG. 3 will be described below. In the shift register as shown in FIG. 3, except for the last stage of shift register unit circuit, the remaining respective stages of shift register unit circuits provide valid scanning signals for gate lines. The shift register unit circuit as shown in FIG. 3 is composed of multiple shift register unit circuits as shown in FIG. 1 or FIG. 2 connected in cascades. Therefore, the operation principle of the shift register unit circuit that provides the valid scanning signals for the gate lines will be described by taking the circuit diagram of the shift register unit circuit as shown in FIG. 2 as an example. The operation process of the shift register unit circuit as shown in FIG. 2 is a cycle of five phases. The operation processes of the five phases will be described below.

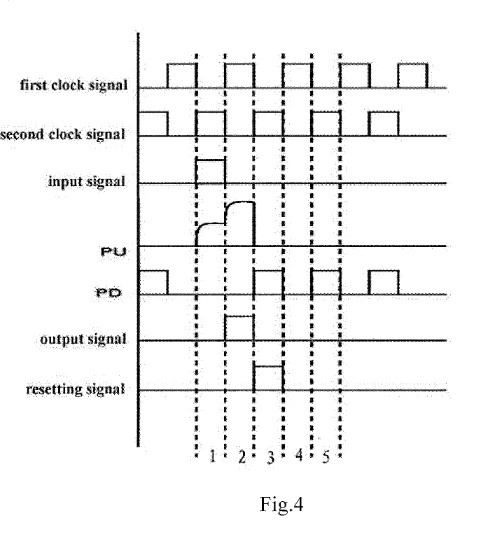

FIG. 4 illustrates a logic timing diagram of the shift register unit circuit as shown in FIG. 2. As shown in FIG. 4, in a first phase, the first clock signal and the signal input by the signal resetting terminal are at a low level, and the second clock signal and the signal input by the signal input terminal are at the high level. Since the signal input by the signal input terminal is at the high level and the first clock signal is at the low level, the first thin film transistor T1 in FIG. 2 is turned on and makes the capacitor C1 charged, so that the potential at the pulling-up node PU located at a positive electrode of the capacitor C1 is pulled up. At the same time, the fourth thin film transistor T4 is turned on, and the potential at the pulling-down node PD located at the source of the third thin film transistor T3 is at the low level at this time, so that the fifth thin film transistor T5 and the sixth thin film transistor T6 are turned off, and the signal output terminal outputs the low level signal.

In a second phase, the signal input by the signal input terminal, the signal input by the signal resetting terminal and the second clock signal are at the low level, and the first clock signal is at the high level. Since the signal input by the signal input terminal is at the low level, the first thin film transistor T1 in FIG. 2 is turned off and the pulling-up node PU continues to keep the high potential. Due to the first clock signal being at the high level, the bootstrap effect amplifies the voltage at the pulling-up node PU, at the same time, the second thin film transistor T2 is in a turn-on state, and thus the potential at the pulling-down node PD is a low potential, the fifth thin film transistor T5 and the sixth thin film transistor T6 are turned off, and at this time the output terminal outputs the high level signal.

In a third phase, the second clock signal and the signal input by the signal resetting terminal are at the high level, the first clock signal and the signal input by the signal input terminal are at the low level, and thus the high level signal input by the signal resetting terminal makes the seventh thin film transistor T7 and the eighth thin film transistor T8 in FIG. 2 turned on, the potential at the pulling-down node PD is a high potential, and the fifth thin film transistor T5 and the sixth thin film transistor T6 are turned on, so that the potentials at the signal output terminal and the pulling-up node PU are the low potential.

In a fourth phase, the first clock signal is at the high level, the second clock signal, the signal input by the signal input terminal and the signal input by the signal resetting terminal are at the low level. At this time, the second thin film transistor T2 in FIG. 2 is turned off, both the potentials at both the pulling-up node PU and the pulling-down node PD are the low potential, and the signal output by the signal output terminal is at the low level.

In a fifth phase, the second clock signal is at the high level, the first clock signal, the signal input by the signal input terminal and the signal input by the signal reset terminal are at the low level. At this time, the potential at the pulling-down node PD in FIG. 2 is a high potential, the fifth thin film transistor T5 and the sixth thin film transistor T6 are turned on to eliminate noise influence in the circuit, and the signal output by the signal output terminal is at the low level.

There further provides in the embodiments of the present disclosure an array substrate comprising the shift register provided in the embodiments of the present disclosure.

There further provides in the embodiments of the present disclosure a display device comprising the array substrate provided in the embodiments of the present disclosure.

The shift register unit circuit provided in the embodiments of the present disclosure adopts a relatively small number of thin film transistors to suppress interference noise in the circuit, which saves wiring space, reduces the area occupied by the shift register unit circuit while realizing signal transmission function and noise reduction function of the shift register unit circuit, so as to realize the narrow frame of the liquid crystal display using the shift register.

Obviously, those skilled in the art can make various alternations and modifications to the present disclosure without departing from the spirit and scope of the present disclosure. As such, if these alternations and modifications of the present disclosure fall into a scope of the claims of the present disclosure and their equivalent technology, then the present disclosure intends to include these alternations and modifications.

The present application claims the priority of Chinese Patent Application No. 201310393435.2 filed on Sep. 2, 2013, the full text of which is incorporated herein as part of the present disclosure by reference.

1. A shift register unit circuit, comprising:
an input module configured to receive an input signal, and output the input signal to a pulling-up node;
an output module configured to receive the input signal, and output a driving signal under a control of a first clock signal;
a pulling-down module configured to pull down a potential at the pulling-up node, and a signal output terminal under a control of a pulling-down node;
a pulling-down control module configured to pull down the pulling-down node under a control of the input signal, and pull up the pulling-down node under a control of a second clock signal; and
a resetting module configured to reset the potential at the pulling-up node and the signal output terminal under a control of a resetting signal.

2. The shift register unit circuit according to claim wherein the input module comprises: a first thin film transistor, whose gate and drain are connected to a signal input terminal, and source is connected to the pulling-up node.

3. The shift register unit circuit according to claim 1, wherein the output module comprises:
a second thin film transistor, whose gate is connected to the pulling-up node, drain is connected to a first clock signal input terminal, and source is connected to the signal output terminal; and
a capacitor, whose first electrode is connected to the pulling-up node and second electrode is connected to the signal output terminal.

4. The shift register unit circuit according to claim 3 wherein the pulling-down control module comprises:
a third thin film transistor, whose drain and gate are connected to a second clock signal input terminal, and a source is connected to the pulling-down node; and
a fourth thin film transistor, whose gate is connected to the signal input terminal, drain is connected to the source of the third thin film transistor, and source is connected to a low voltage level input terminal.

5. The shift register unit circuit according to claim 4, wherein the pulling-down module comprises:
a fifth thin film transistor, whose gate is connected to the pulling-down node, drain is connected to the pulling-up node, and source is connected to the low voltage level input terminal; and
a sixth thin film transistor, whose gate is connected to the pulling-down node, drain is connected to the signal output terminal, and source is connected to the low voltage level input terminal.

6. The shift register unit circuit according to claim 5, wherein the resetting module comprises:
a seventh thin film transistor, whose gate is connected to a signal resetting terminal, source is connected to the low voltage level input terminal, and drain is connected to the pulling-up node; and
an eighth thin film transistor, whose gate is connected to the signal resetting terminal, drain is connected to the signal output terminal, and source is connected to the low voltage level input terminal.

7. A shift register comprising multiple stages of shift register unit circuits according to claim 1 connected in cascades, wherein an input signal of a first stage of shift register unit circuit is a frame start signal, except for the first stage of shift register unit circuit, input signals of remaining respective stages of shift register unit circuits are output signals of a previous stage of shift register unit circuit; except for a last stage of shift register unit circuit, resetting signals of remaining respective stages of shift register unit circuits are output signals of a next stage of shift register unit circuit.

8. An array substrate comprising the shift register according to claim 7.

9. (canceled)

10. The shift register according to claim 7, wherein the input module comprises:
a first thin film transistor, whose gate and drain are connected to a signal input terminal, and source is connected to the pulling-up node,

11. The shift register according to claim 10, wherein the output module comprises:
a second thin film transistor, whose gate is connected to the pulling-up node, drain is connected to a first clock signal input terminal, and source is connected to the signal output terminal; and
a capacitor, whose first electrode is connected to the pulling-up node and second electrode is connected to the signal output terminal.

12. The shift register according to claim 11, wherein the pulling-down control module comprises:
a third thin film transistor, whose drain and gate are connected to a second clock signal input terminal, and a source is connected to the pulling-down node; and
a fourth thin film transistor, whose gate is connected to the signal input terminal, drain is connected to the source of the third thin film transistor, and source is connected to a low voltage level input terminal.

13. The shift register according to claim 12, wherein the pulling-down module comprises:
a fifth thin film transistor, whose gate is connected to the pulling-down node, drain is connected to the pulling-up node, and source is connected to the low voltage level input terminal; and
a sixth thin film transistor, whose gate is connected to the pulling-down node, drain is connected to the signal output terminal, and source is connected to the low voltage level input terminal.

14. The shift register according to claim 13, wherein the resetting module comprises:
a seventh thin film transistor, whose gate is connected to a signal resetting terminal, source is connected to the low voltage level input terminal, and drain is connected to the pulling-up node; and
an eighth thin film transistor, whose gate is connected to the signal resetting terminal, drain is connected to the signal output terminal, and source is connected to the low voltage level input terminal.

15. The array substrate according to claim wherein the input module comprises:
a first thin film transistor, whose gate and drain are connected to a signal input terminal, and source is connected to the pulling-up node.

16. The array substrate according to claim 15, wherein the output module comprises
a second thin film transistor, whose gate is connected to the pulling-up node, drain is connected to a first clock signal input terminal, and source is connected to the signal output terminal; and
a capacitor, whose first electrode is connected to the pulling-up node and second electrode is connected to the signal output terminal.

17. The array substrate according to claim 16, wherein the pulling-down control module comprises:
a third thin film transistor, whose drain and gate are connected to a second clock signal input terminal, and a source is connected to the pulling-down node; and
a fourth thin film transistor, whose gate is connected to the signal input terminal, drain is connected to the source of the third thin film transistor, and source is connected to a low voltage level input terminal

18. The array substrate according to claim 17, wherein the pulling down module comprises:
a fifth thin film transistor, whose gate is connected to the pulling-down node, drain is connected to the pulling-up node, and source is connected to the low voltage level input terminal; and
a sixth thin film transistor, whose gate is connected to the pulling-down node, drain is connected to the signal output terminal, and source is connected to the low voltage level input terminal

19. The array substrate according to claim 18, wherein the resetting module comprises:
a seventh thin film transistor, whose gate is connected to a signal resetting terminal, source is connected to the low voltage level input terminal, and drain is connected to the pulling-up node; and
an eighth thin film transistor, whose gate is connected to the signal resetting terminal, drain is connected to the signal output terminal, and source is connected to the low voltage level input terminal.
